(19) United States
(12) Patent Application Publication
(10) Pub. No.: US 2008/0038532 A1
(43) Pub. Date: Feb. 14, 2008

(54) METHOD OF FORMING NANOPARTICLE ARRAY USING CAPILLARITY AND NANOPARTICLE ARRAY PREPARED THEREBY

(75) Inventors: Dong Kee YI, Seoul (KR); June Mo KOO, Yongin-si (KR); Seong Jae CHOI, Seoul (KR); Jae Young CHOI, Suwon-si (KR); Young Kwan CHA, Suwon-si (KR); Hyo Sug LEE, Suwon-si (KR); Hyuk Soon CHOI, Seongnam-si (KR); Kwang Hee KIM, Seoul (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/680,277

(22) Filed: Feb. 28, 2007

(30) Foreign Application Priority Data
May 26, 2006 (KR) 10-2006-0047462

(51) Int. Cl. B32B 27/32; B05D 1/12; H01L 21/20

(52) U.S. Cl. 428/220; 427/180; 438/478; 257/E21.09; 977/774

(57) ABSTRACT

Disclosed are a method of forming a nanoparticle array, including preparing a trench having a channel structure between upper and lower substrates, preparing a dispersion of nanoparticles, and bringing the trench into contact with the dispersion such that the dispersion enters the channel of the trench due to capillary force, and a nanoparticle array prepared thereby. According to this invention, the nanoparticles may be uniformly arranged at a high density on a substrate having a large area at low cost.

This non-provisional application claims priority to Korean Patent Application No. 10-2006-0047462 filed on May 26, 2006, and all the benefits accruing therefrom under U.S.C. §119(a), the content of which is herein incorporated by reference in its entirety.

### BACKGROUND OF THE INVENTION

1. Field of the Invention

The present invention relates, generally, to a method of forming a nanoparticle array using capillarity and a nanoparticle array prepared thereby. More particularly, the present invention relates to a method of forming a nanoparticle array, which comprises supplying nanoparticles into the channel structure of a trench using capillary force in order to uniformly arrange the nanoparticles on a substrate having a large area, and to a nanoparticle array prepared thereby.

2. Description of the Related Art

Nanoparticle array techniques for arranging nanoparticles having sizes from less than one to tens of nanometers (nm) in average diameter to have a uniform surface density over a large area are useful in various fields including information storage, memory devices, optical devices, and optoelectronics. For example, techniques for arranging quantum dots composed of a nanoparticulate semiconductor compound may be applied to optical devices capable of controlling light wavelengths through determination of the size of the quantum dots and having high quantum efficiency, next-generation recording media, and single electron transistors and single electron memory as a next-generation semiconductor device using a coulomb blockade effect of the electrical charges stored in the quantum dots. Further, techniques for arranging nanosized metal particles, such as Au, Ag or Fe, to form useful arrays, are popular in the field of information storage or memory.

Thorough research into the arrangement of nanoparticles has been conducted to date, but it has been difficult to realize mass production generally due to high process precision and/or a high preparation cost. In particular, arrangement methods using convection arrays have been disclosed (Mun Ho Kim, Sang Hyuk Im, O Ok Park Advanced Functional Material 2005, 15, 1329-1335). However, since such arrangement methods are used to arrange nanoparticles having a size of hundreds of nm or larger, they are unsuitable for use in the arrangement of nanoparticles having a size from ones to tens of nm. Moreover, in such techniques, hot, dry air is sprayed onto a colloidal solution, thereby evaporating the colloidal solution and leading to the adhesion of nanoparticles. When air is directly sprayed onto the nanoparticles having a small size, the arrangement of nanoparticles is broken down by spray pressure and turbulence attributable thereto.

Conventionally, known methods of forming a nanoparticle array can include modifying the surface of quantum dot to electrically charge it and to prepare a quantum dot dispersion; modifying the surface of a substrate to impart the opposite electrical charges to the substrate and the quantum dot; and applying the quantum dot dispersion onto the substrate thus pretreated. As such, methods of using a polymer as a material for modifying the surface of the quantum dot are also known. However, such methods suffer because defects or voids can occur in which nanoparticles are not formed, undesirably decreasing the uniformity of a monolayer array. Further, since the polymer remains as an impurity, the properties of the nanoparticle array may be diminished. For these reasons, it can be difficult to realize a monolayer array over a large area.

Alternatively, methods of forming a nanoparticle array, comprising injecting nanoparticle suspension drops between two glass slides facing each other with a predetermined interval therebetween, and transferring the upper slide to move the meniscus of the drops, have been proposed.

In addition, a Langmuir-Blodgett (“LB”) method of arranging nanoparticles adsorbed on the surface of a substrate by removing the substrate from a nanoparticle solution is known. According to this method, although the nanoparticles may be arranged in a monolayer on a substrate having a large area, defects or voids may be easily formed in the resultant nanoparticle array.

### BRIEF SUMMARY OF THE INVENTION

Accordingly, in view of the foregoing deficiencies of the prior art, disclosed herein is a method of forming a nanoparticle array, in which nanoparticles having a size from ones to tens of nm can be uniformly arranged on a substrate having a large area, and a nanoparticle array prepared thereby.

In an embodiment, a method of forming a nanoparticle array is provided, in which nanoparticles can be regularly arranged on a substrate having a large area, and a nanoparticle array prepared thereby.

In another embodiment, a method of forming a nanoparticle array is provided, in which the monolayer array of nanoparticles can be obtained at a low cost while achieving the above objects, and a nanoparticle array prepared thereby.

In a further embodiment, a method of forming a nanoparticle array is provided which uses capillarity, the method comprising: preparing a trench having a channel structure between an upper substrate and a lower substrate; dispersing nanoparticles in an aqueous solution or an organic solvent, thus obtaining a nanoparticle dispersion; bringing the trench into contact with the dispersion such that the dispersion enters the channel structure of the trench due to capillary force; and evaporating the solvent.

In another embodiment, a nanoparticle array is prepared using the above method.

In another embodiment, an electronic device comprises the above nanoparticle array.

In another embodiment, a trench for forming the nanoparticle array is provided, comprising a lower substrate, pins formed on both sides of a surface of the lower substrate, and an upper substrate placed on a surface of the pins opposite the lower substrate, wherein a channel structure defined by the upper substrate, the lower substrate, and the pins is nanosized such that a nanoparticle dispersion rises therein due to capillary force.

### BRIEF DESCRIPTION OF THE DRAWINGS

The above and other features and advantages of the present invention will be more clearly understood from the following detailed description taken in conjunction with the accompanying drawings, in which:

FIG. 1 is a perspective view of an exemplary trench used in the process of forming a nanoparticle array according to the present invention;

FIG. 2A is a side sectional view of a trench used in an exemplary process of forming a nanoparticle array, according to a first embodiment;

FIG. 2B is a side sectional view of a trench showing an exemplary process of forming a nanoparticle array, according to a second embodiment, using the trench of FIG. 2A;

FIGS. 3A and 3B are scanning electron microscope (“SEM”) pictures of exemplary nanoparticle arrays prepared in Examples 1 and 2;

FIGS. 4A and 4B are SEM pictures of exemplary nanoparticle arrays formed on an upper substrate and a lower substrate in Example 3;

FIG. 5 is an SEM picture of an exemplary nanoparticle array prepared in Example 4; and

FIGS. 6A and 6B are atomic force microscope (“AFM”) images of an exemplary nanoparticle array prepared in Example

### DETAILED DESCRIPTION OF THE INVENTION

Hereinafter, a detailed description will be given of the present invention, with reference to the appended drawings.

It will be understood in the following disclosure of the present invention, that as used herein, the singular forms “a”, “an” and “the” are intended to include the plural forms as well, unless the context clearly indicates otherwise. It will be further understood that the terms “comprise”, “comprises”, and “icomprising,” when used in this specification, specify the presence of stated features, integers, steps, operations, elements, components, and combination of the foregoing, but do not preclude the presence and/or addition of one or more other features, integers, steps, operations, elements, components, groups, and combination of the foregoing.

It will be understood that when an element is referred to as being “on” another element, or when an element is referred to as being “disposed between” two or more other elements, it can be directly on (i.e., in at least partial contact with) the other element(s), or an intervening element or elements may be present therebetween. In contrast, when an element is referred to as being “disposed on” another element, the elements are understood to be in at least partial contact with each other, unless otherwise specified. Spatially relative terms, such as “between”, “in between” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. The device may be otherwise oriented (rotated 90 degrees, inverted, or at other orientations) and the spatially relative descriptors used herein interpreted accordingly. Likewise, use of the term “opposite”, unless otherwise specified, means on the opposing side or surface of the element. For example, where a surface of a layer is said to be opposite another surface or element, it is located on the opposing surface of the layer coplanar with the first surface unless otherwise specified.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The method of forming a nanoparticle array disclosed herein is characterized in that nanoparticles are dispersed in an aqueous solution or an organic solvent to obtain a nanoparticle dispersion, and the nanoparticle dispersion is then injected into the nanosized channel of a trench using capillary force, thus forming a two-dimensional nanoparticle array.

Specifically, in the method, a trench having a channel structure between upper and lower substrates is first prepared. Separately from the preparation of the trench, nanoparticles are dispersed in an aqueous solution or an organic solvent, thus obtaining a nanoparticle dispersion. As disclosed herein, the term “nanoparticles” may be interpreted broadly to include all types of nanoparticles. Exemplary nanoparticles can include quantum dots as semiconductor nanoparticles, metallic nanoparticles composed of metal such as Au, Ag, Fe, Co, Ni, or Pt, metal oxide nanoparticles, nanosized polymer beads, and dendrimers. When both the trench and the nanoparticle dispersion are prepared, the trench is brought into contact with the dispersion such that the dispersion enters the channel of the trench due to capillary force to coat the substrate, and the solvent is evaporated to attach the nanoparticles to the substrate.

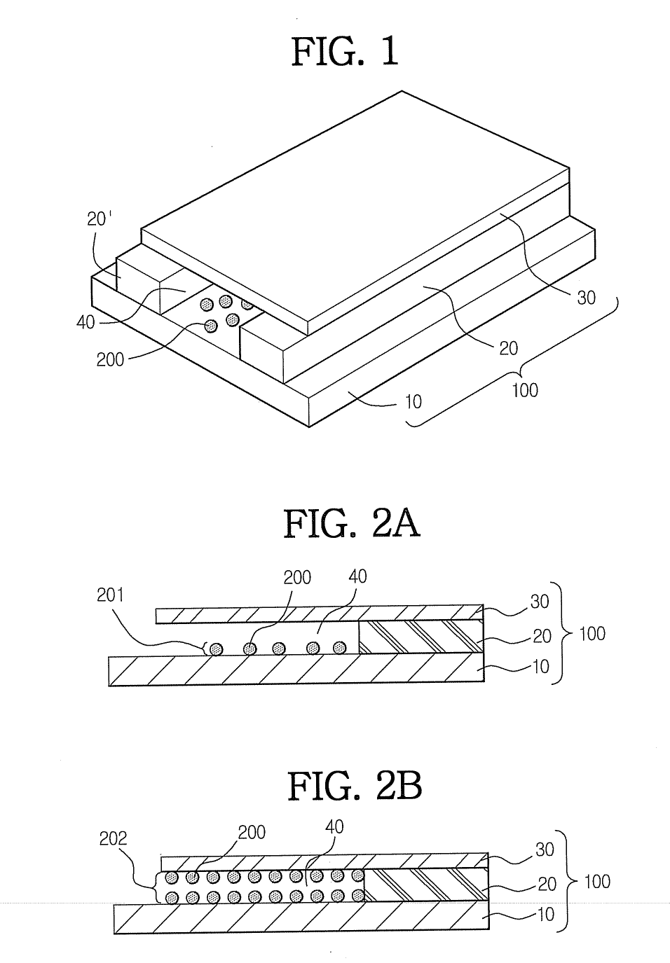

The method of forming the nanoparticle array of the present invention is described stepwise, below. FIG. 1 is a perspective view of the trench used in the process of forming the nanoparticle array according to the present invention, and FIG. 2A is a side sectional view of the trench used in the process of forming the nanoparticle array according to the present invention.

a) Formation of Trench

In FIGS. 1 and 2A, a trench 100 is prepared by forming pins 20, 20′ on both sides of a surface of a lower substrate and placing an upper substrate 30 on a surface of the pins opposite the lower substrate, resulting in a nanosized channel structure 40 capable of being used to supply the nanoparticles to the substrate surfaces between the pins.

The process of forming the pins 20, 20′ is not particularly limited. For example, the pins 20, 20′ may be formed through Atomic Layer Deposition (“ALD”) on a surface of the lower substrate 10. ALD is a process of depositing thin films in a manner such that one atomic layer is produced at a time on the substrate, and thus is advantageously used in herein because a very thin film may be deposited, and the thickness of the film may also be precisely controlled. Therefore, the ALD may be used to form pins having a very small width to a uniform thickness as in the present invention.

Upon deposition of the thin film by ALD, a pin may be formed of material such as, for example, Al₂O₃, SiO₂, HfO₂, Ta₂O₅ and TiO₂. In an embodiment, trimethyl silane or trimethyl aluminum may be used as ALD precursors to the pins 20, 20′.

Alternatively, the pin may be formed by imaging and etching of a thin film layer, by for example using photolithography followed by a reactive ion etch. Specifically, a thin film layer useful for formation of the pin is prepared, coated with a photoresist composition, exposed through a photomask, and then developed, thus forming a pin pattern in positive or negative tone. In an embodiment, a positive tone photoresist is used. The portion of the thin film layer corresponding to the channel structure may be removed by a dry etching process, such as by plasma etching. In the plasma etching, ionic particles of plasma accelerated in a perpendicular direction, may be used to etch the exposed portion through physical impact and chemical reaction. The channel portion can thus be selectively etched using an etching mask.

In FIGS. 1, 2A, and 2B, the channel structure 40 of the trench 100 formed between the pins 20, 20′ on both sides of a surface of the lower substrate has, in an embodiment, a width of 2 to 4 cm, a height of 20 to 200 nm, and a length of 1 to 10 cm. As used herein, the term “length” refers to the dimension coincident with the open end or ends of the channel structure of the trench into which the nanoparticle dispersion enters the channel structure. Also as used herein, the term “width” refers to the cross-sectional (i.e., transverse) dimension of the channel structure of the trench, orthogonal to the length. Also as used herein, the term “height” refers to the dimension of the trench orthogonal to both the length and width. Upon the formation of the pins 20, 20′, it is desirable that the distance between the two pins and the height of the pins be adjusted within the above range, inclusive of the endpoints of the range. It is noted that pin 20′ is not shown in FIGS. 2A and 2B but can be present in an embodiment. In an embodiment, the pins 20, 20′ are formed on the same surface of the lower substrate 10.

Also in FIG. 1, after the formation of the pins 20, 20′ on both sides of a surface of the lower substrate 10, the upper substrate 30 is placed on a surface of the pins 20, 20′ opposite the lower substrate 10, and then may be secured thereto by the application of pressure, or in another embodiment may be attached using an adhesive. In an embodiment, the upper substrate 30 is not completely attached to the pins 20, 20′, and the upper substrate 30 may be removed. Further, in another embodiment, the upper substrate 30 is removably attached to the pins 20, 20′ (FIG. 1), and the nanoparticles 200 may form a nanoparticle array 202 that is disposed not only on the lower substrate 10 but also on a surface of the upper substrate 30 facing lower substrate 10, as shown in FIG. 2B.

In an embodiment, the lower and upper substrates 10, 30 respectively are formed using a material having high wettability and thus facilitating the dispersion of nanoparticles. Examples of materials useful in upper and lower substrates 10, 30 respectively include, but are not limited to, SiO₂, TiO₂, indium tin oxide (“ITO”), fluorine-doped tin oxide (“FTO”), Fe₂O₃, FePt, Al₂O₃, GaAs, GaN, TaOₓ (1<x≦4), polystyrene, polyethylene terephthalate, polycarbonate, and carbon nanotubes. The materials for the lower and upper substrates 10, 30 respectively, and the pins 20, 20′ may be the same as or different from each other.

The dispersion rises along the channel structure 100 due to capillary force between the lower and upper substrates 10, 30 respectively, and the nanoparticle dispersion. When the solvent is removed in a subsequent process, the nanoparticles 200 (e.g., quantum dots) are applied to the lower substrate 10 and form a nanoparticle array 201 (in FIG. 2A) having a uniform nanoparticle arrangement suitable for use in devices. Thus, sufficient capillary force should be provided between the upper and lower substrates 10, 30 respectively, and the nanoparticle dispersion, to enable the rise of the dispersion along the substrate by capillary force. Thus, the size of the channel structure of the trench should be designed in consideration of the above aspect.

b) Preparation of Nanoparticle Dispersion

In order to supply the nanoparticles into (in FIG. 1) the channel structure 40 of the trench 100 using capillary force, the dispersion of the nanoparticles 200 is prepared. As such, the dispersion of the nanoparticles 200 is in a colloidal state in which the nanoparticles 200 do not agglomerate but are uniformly dispersed.

The nanoparticles usable in the present invention can include any or all of metallic nanoparticles, metal oxide nanoparticles, semiconductor nanoparticles, polymer nanoparticles, dendrimers, or magnetic nanoparticles, each having an average diameter (also referred to as “average particle size”) of 10 nm or less. Examples of the metallic nanoparticles include materials selected from the group consisting of Pt, Au, Ag, Fe, Co, Ni, Pd, Al, Cu, Si, Ge, or alloys thereof, and examples of the metal oxide nanoparticles include materials selected from the group consisting of ZnO, TiO₂, CuO, Fe₂O₃, or SiO₂. The magnetic nanoparticles are exemplified by materials selected from the group consisting of FeO or FePt.

Examples of polymer nanoparticles useful herein include, but are not limited to, materials selected from the group consisting of polystyrene, polymethylmethacrylate, polyaniline, polycyclodextrin, polyacrylic acid, polyamide, or proteins.

In an embodiment, the nanoparticles include semiconductor nanoparticles (i.e., quantum dots) having a quantum confinement effect in which such quantum dots may have a homogeneous monolayer structure or a double-layer structure composed of a core and a shell.

The quantum dots may be selected from the group consisting of compound semiconductors comprising materials comprising, for example Group 2-6 compounds, Group 2-5 compounds, Group 3-6 compounds, Group 3-5 compounds, Group 4-6 compounds, Group 1-3-6 compounds, Group 2-4-6 compounds, and Group 2-4-5 compounds. As used hereinabove, where hyphenated group numbers are used, a combination of the groups is indicated, e.g., a Group 2-6 compound is a compound including an element of Group 2 and an element of Group 6. Specific examples of such quantum dots include, but are not limited to, those comprising materials including CdS, CdSe, CdTe, ZnS, ZnSe, ZnTe, GaN, GaP, GaAs, GaSb, AlN, AlP, AlAs, AlSb, InP, InAs, and InSb.

Where quantum dots having a core-shell structure are used, the core may be overcoated with a material selected from the group consisting of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, and mixtures thereof.

The solvent used to disperse the nanoparticles includes an aqueous solvent such as water or an organic solvent. As disclosed herein, useful solvents include those selected from the group consisting of chloroform, N-methylpyrrolidone, acetone, cyclopentanone, cyclohexanone, methylethylketone, ethylcellosolve acetate, butyl acetate, ethyleneglycol, toluene, xylene, tetrahydrofuran, dimethylformamide, chlorobenzene, and acetonitrile, where the solvents can be used alone, or two or more solvents may be used together in a predetermined ratio.

In an embodiment, in the case where water is used as the solvent, the nanoparticles can be surface modified to polarize the surface thereof. The nanoparticles are generally prepared through a wet chemical process, and have various types of ligands (trioctyl amine, trioctyl phosphine oxide, oleic acid, oleyl amine, glutathione, and the like) disposed on the surface thereof. Almost all the ligands, in addition to glutathione, are non-polar compounds and thus have low dispersibility in water. Hence, in order to increase the dispersibility of a ligand in water, a polar ligand, such as but not limited to for example polyacrylic acid, mercaptoacetic acid, undecanoic acid, polyethylene oxide, dodecanoic acid, a sulfonic acid derivative, or a phosphoric acid derivative, is attached to the surface of the nanoparticles and the polar group is oriented toward water so as to increase the dispersibility in water.

c) Injection of Dispersion

In FIGS. 1, 2A and 2B, when the trench 100 and the dispersion of the nanoparticles 200 are prepared, the dispersion of the nanoparticles 200 is injected into the channel structure 40 of the trench 100 using lateral capillary force. As mentioned above, since the channel structure of the trench has a width of 2 to 4 cm and a height of 20 to 100 nm, the end of the trench 100 is brought into contact with the dispersion so that the dispersion of the nanoparticles 200 rises along the channel structure 40 due to capillarity. That is, the dispersion of the nanoparticles 200 rises along the channel structure using capillary force caused by the relative difference of adhesion between the substrates 10, 30 of the trench 100 and the dispersion of the nanoparticles 200, and cohesion between the solvent molecules of the dispersion of nanoparticles.

d) Evaporation of Solvent

After the dispersion of the nanoparticles 200 enters the channel structure 40 using capillary force and thus is applied on the upper and/or lower substrates 10, 30 respectively, the solvent is evaporated such that the nanoparticles 200 adhere to a surface of the upper and/or lower substrates 10, 30 respectively. That is, while the solvent loaded in the nanoparticles is evaporated, a concave interface results, and the nanoparticles 200 are mutually closely attracted to one another by lateral surface tension to minimize the surface energy of the interface. Further, when the excess dispersion contained in the nanoparticles 200 is evaporated, the nanoparticles 200, which are dispersed at sufficient intervals, are subsequently brought into close contact with one another by Van der Waals force, and adhere to the lower substrate. In this way, when the solvent is evaporated, the nanoparticles 200 may spontaneously form into a nanoparticle array 201 (in FIG. 2A) or 202 (in FIG. 2B) having a well-ordered monolayer structure with a uniform arrangement of the nanoparticles 200.

The process of evaporating the solvent is not particularly limited. For example, the trench coated with the dispersion of the nanoparticles may be dried in an oven at 30 to 50° C. for 24 to 60 hours. In this case, the drying temperature or time may vary depending on the type of solvent used. Alternatively, an electrical resistance heating process or a slow drying process are useful, as accomplished by positioning a thermal strip on a surface of a substrate or by illuminating the solution positioned at the end of the substrate with a laser.

In the nanoparticle array prepared using the method disclosed herein, nanoparticles having a size of 10 nm or less are in close contact with one another and thus have a dense and uniform arrangement. The nanoparticle array of the present invention is formed to a high density of 2×10¹² nanoparticles/cm², and is substantially free of voids or defects without nanoparticles in the nanoparticle array. As used herein, “substantially free of” means that the number of voids present, if any, are sufficiently few in number such that any such voids would not significantly adversely affect the desired properties of the nanoparticle array. Also, the nanoparticle array has an arrangement of properties not greatly affected by the surface of the substrate or the electrical charges of the particles.

The nanoparticle array formed using the method disclosed herein may be used in various electronic devices to which the nanoparticles are applied, such as, for example, quantum dot displays, charge trap memory chips, biosensors, optical devices, and magnetic devices.

In addition, a trench useful for the method of forming the nanoparticle array is disclosed. The trench used in the method includes a lower substrate, pins formed on both sides of a surface of the lower substrate, and an upper substrate disposed on a surface of the pins opposite the lower substrate, in which the channel structure defined by the upper and lower substrates and both the pins is characterized in that it has nanosized dimensions suitable for rise of the nanoparticle dispersion into the channel structure using capillary force.

A better understanding of the present invention may be obtained in light of the following examples, which are set forth to illustrate, but should not to be construed as limiting to, the present invention.

### EXAMPLE 1

1.8424 g of mercapto acetic acid (“MAA”) was dissolved in 8 ml of chloroform and then heated to 70° C. The solution, heated to 70° C., was slowly added with 3 ml of CdSe/ZnS quantum dots while being rapidly stirred. Subsequently, the solution was reacted while being stirred at 70° C. for 3 hours under a reflux condition. After the completion of the reaction, procedures of centrifuging the reacted solution at 3,000 rpm to form a precipitate, dispersing the precipitate in chloroform, and centrifuging the dispersion at 3,000 rpm for 5 min to form a precipitate were repeated seven times. The washed quantum dots were vacuum dried for 6 hours and then dispersed in a trishydroxymethylamino ethane(“Tris”) buffer solution (0.1 M, pH=9), after which the dispersion was centrifuged at 15,000 g for 10 min and the agglomerated quantum dots were removed, thus preparing a quantum dot dispersion in Tris buffer solution.

Thereafter, a glass substrate with 3 cm×3 cm×0.8 cm sized features was treated with a piranha solution (1:3 v/v H₂SO₄/H₂O₂), heated for 15 min, and then washed with methanol/toluene. Using an ALD process, SiO₂ was deposited piecemeal in successive layers using a trimethyl silane precursor, and the layered SiO₂ was patterned by photolithography and etched to form pins for a channel structure having a width of 2.5 cm, a height of 20 nm, and a length of 1 cm, after which the pins were covered with an upper glass substrate of the same as the lower substrate.

Subsequently, the trench was brought into contact with the quantum dot dispersion such that the quantum dot dispersion rose therein due to capillary force to apply the quantum dot dispersion on the substrate, followed by drying the substrate at 52° C. for 60 hours and cooling it at room temperature, thereby forming a quantum dot array.

### EXAMPLE 2

A nanoparticle array was prepared in the same manner as in Example 1, with the exception that the depth of the trench formed (i.e., as determined by the height of the pins, and corresponding to the height dimension of the channel structure, as disclosed herein) was 100 nm.

### EXAMPLE 3

A nanoparticle array was prepared in the same manner as in Example 1, with the exception that a trench formed of HfO₂ was used and the nanoparticles were deposited and arrayed on each of the lower substrate and the upper substrate surfaces in the trench.

### EXAMPLE 4

A nanoparticle array was prepared in the same manner as in Example 1, with the exception that the HfO₂ substrate was used and the depth of the trench was 40 nm.

### EXPERIMENTAL EXAMPLE 1

### Measurement of Packing Density

The packing density of the nanoparticle array of each of Examples 1 to 4 was measured. The results are given in Table 1 below. As such, the packing density was determined by obtaining the SEM picture of the sample, randomly selecting 10 regions of a known area dimension thereon, measuring the number of nanoparticles in the region, and normalizing to provide the number of nanoparticles per 1 cm².

TABLE 1

| Ex. | | Depth of | Packing Density |
|---|---|---|---|
| No. | Trench Material | Trench | (nanoparticles/cm²) |
| 1 | SiO₂ | 40 nm | 1.9 × 10¹² |
| 2 | SiO₂ | 100 nm | 2.0 × 10¹² |
| 3 | HfO₂ | 40 nm | 1.7 × 10¹² |
| | (upper substrate) | | |
| | HfO₂ | 40 nm | 1.7 × 10¹² |
| | (lower substrate) | | |
| 4 | HfO₂ | 40 nm | 1.86 × 10¹² |

### EXPERIMENTAL EXAMPLE 2

### Observation of SEM Pictures

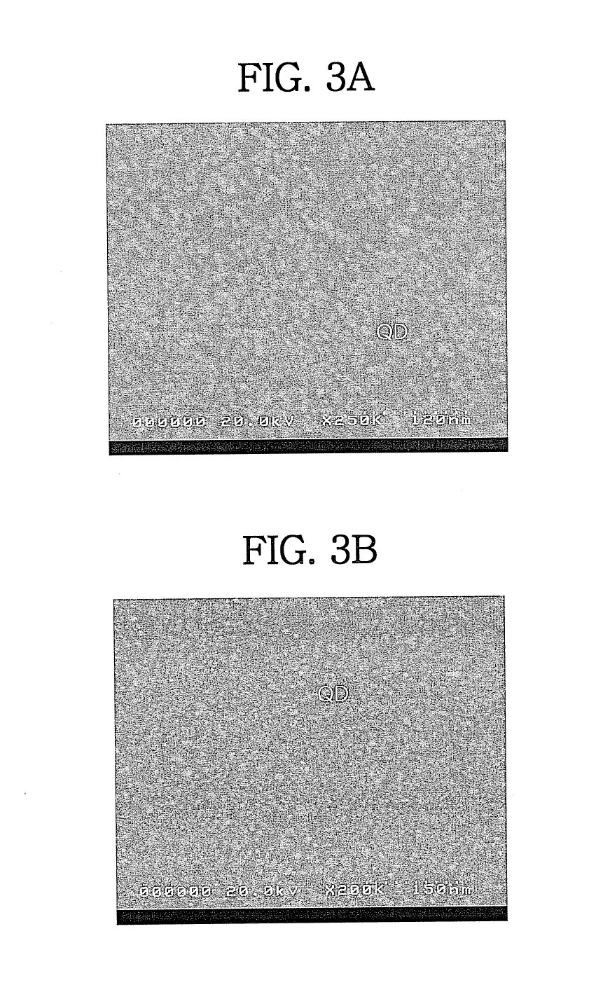

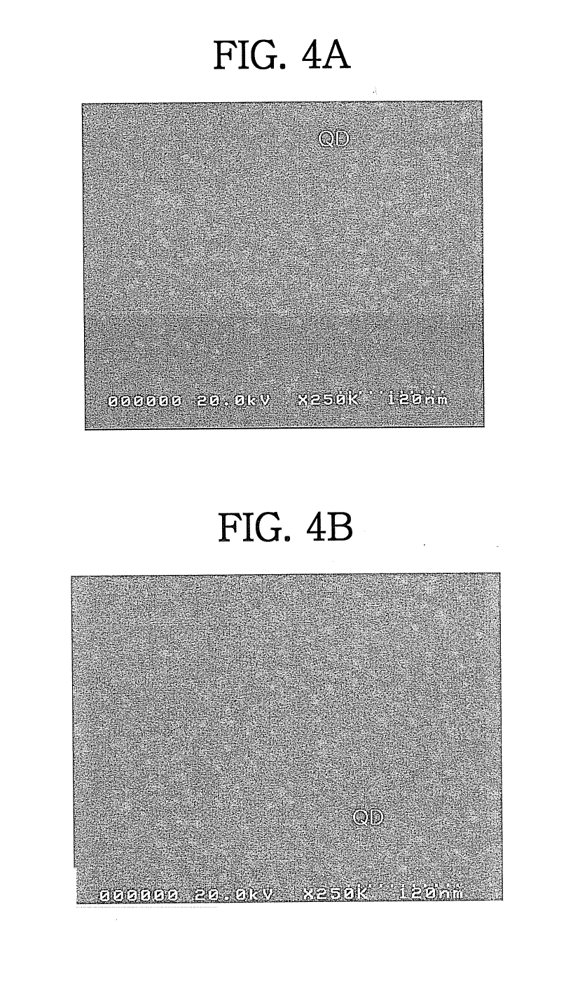

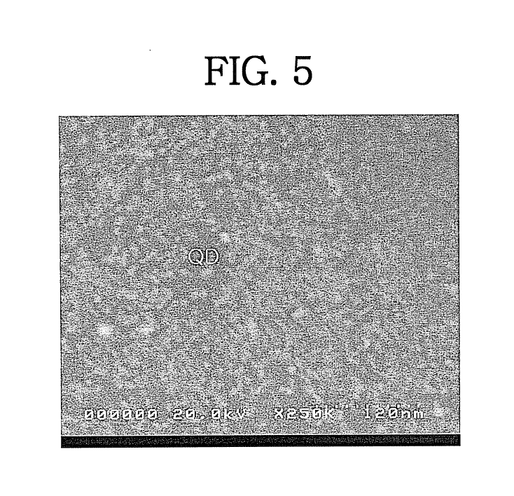

The SEM pictures of the nanoparticle arrays obtained in Examples 1 and 2 are shown in FIGS. 3A and 3B. The SEM pictures of the nanoparticle arrays formed on the upper and lower substrates in Example 3 are shown in FIGS. 4A and 4B. The SEM picture of the nanoparticle array prepared in Example 4 is shown in FIG. 5.

As in FIGS. 3A to 5, the nanoparticle array obtained using the method described herein was confirmed to have nanoparticles which were in close contact with one another and were densely arranged.

### EXPERIMENTAL EXAMPLE 3

### Observation of AFM Image

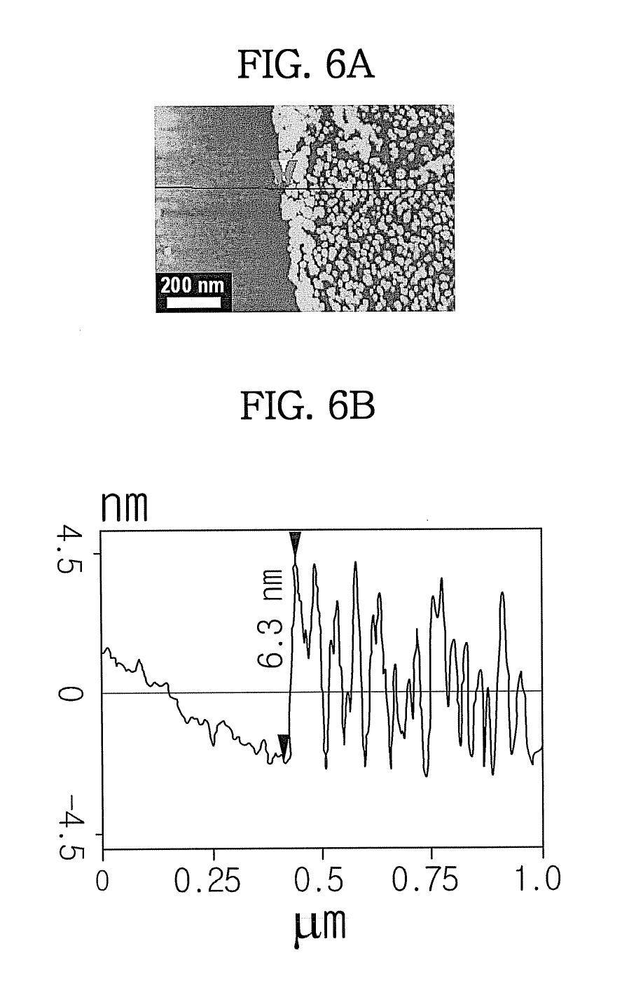

The nanoparticle array obtained in Example 1 was analyzed using an AFM. The result of observation of the AFM image is shown in FIG. 6A, as is the result of measurement of the thickness of the nanoparticle array while scanning predetermined points on the nanoparticle array using a cantilever.

As is apparent from FIG. 6B, the nanoparticles were confirmed to be arranged in a uniform monolayer in Example 1.

As described hereinabove, the present invention provides both a method of forming a nanoparticle array using capillarity and a nanoparticle array prepared thereby. According to the method of forming the nanoparticle array, nanoparticles having an average size (i.e., diameter) of about one to tens of nm can be uniformly arranged on a substrate having a large area.

In the present invention, the dispersion of the nanoparticles enters a trench having a channel structure between upper and lower substrates using capillary force, and therefore the monolayer array of the nanoparticles can be obtained through a one-step process.

Further, according to the present invention, even in the case where the nanoparticles are arranged at a high density, since the nanoparticles are not formed into two layers or more and do not cause defects such as voids, the nanoparticles can be arranged in a monolayer having high uniformity.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of forming a nanoparticle array, comprising:
preparing a trench having a channel structure between an upper substrate and a lower substrate;
dispersing nanoparticles in an aqueous solution or an organic solvent, thus obtaining a nanoparticle dispersion;
bringing the trench into contact with the dispersion such that the dispersion enters the channel structure of the trench due to capillary force; and
evaporating the solvent.

2. The method as set forth in claim 1, wherein the preparing the trench comprises:
forming pins for supply of the nanoparticles on both sides of a surface of the lower substrate; and
placing an upper substrate on a surface of the pins opposite the lower substrate and attaching the upper substrate to a surface of the pins opposite the lower substrate by application of pressure or using an adhesive.

3. The method as set forth in claim 2, wherein the forming the pins is conducted by forming a layer for formation of the pins and etching a portion of the layer corresponding to a channel structure by a photolithography and etch process.

4. The method as set forth in claim 3, wherein the forming the layer for forming the pins is conducted by atomic layer deposition on the surface of the lower substrate.

5. The method as set forth in claim 1, wherein the substrate comprises a material selected from the group consisting of SiO₂, TiO₂, ITO, FTO, Fe₂O₃, FePt, Al₂O₃, GaAs, GaN, TaOₓ (1<x≦4), polystyrene, polyethylene terephthalate, polycarbonate, and carbon nanotubes.

6. The method as set forth in claim 1, wherein the dispersion is a colloidal solution in which the nanoparticles are not agglomerated but are uniformly dispersed.

7. The method as set forth in claim 1, wherein the nanoparticles are selected from the group consisting of metallic nanoparticles, metal oxide nanoparticles, semiconductor nanoparticles, polymer nanoparticles, magnetic nanoparticles, and dendrimers.

8. The method as set forth in claim 7, wherein the metallic nanoparticles comprise a material selected from the group consisting of Pt, Au, Ag, Fe, Co, Ni, Pd, Al, Cu, Si, Ge, alloys thereof, or the metal oxide nanoparticles comprise a material selected from the group consisting of Cuo, Fe₂O₃, and SiO₂.

9. The method as set forth in claim 7, wherein the polymer nanoparticles comprise a material selected from the group consisting of polystyrene, polymethylmethacrylate, polyaniline, polycyclodextrin, polyacrylic acid, polyamide, and proteins.

10. The method as set forth in claim 7, wherein the semiconductor nanoparticles are quantum dots having a core-shell structure or a homogeneous monolayer structure.

11. The method as set forth in claim 10, wherein the quantum dots are selected from the group consisting of Group 2-6 compounds, Group 2-5 compounds, Group 3-6 compounds, Group 3-5 compounds, Group 4-6 compounds, Group 1-3-6 compounds, Group 2-4-6 compounds, and Group 2-4-5 compounds.

12. The method as set forth in claim 11, wherein the quantum dots comprise a material selected from the group consisting of CdS, CdSe, CdTe, ZnS, ZnSe, ZnTe, GaN, GaP, GaAs, GaSb, AlN, AlP, AlAs, AlSb, InP, InAs, and InSb.

13. The method as set forth in claim 12, wherein the quantum dots comprise an overcoating comprising a material selected from the group consisting of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, and mixtures thereof.

14. The method as set forth in claim 1, wherein the nanoparticles have an average particle size of 10 nm or less.

15. The method as set forth in claim 1, wherein the channel structure of the trench has a width of 2 to 4 cm, a height of 20 to 200 nm, and a length of 1 to 10 cm.

16. The method as set forth in claim 1, further comprising surface-modifying the nanoparticles to polarize a surface thereof when water is the solvent.

17. A nanoparticle array, formed using the method of claim 1.

18. An electronic device, comprising the nanoparticle array of claim 17.

19. A trench for forming a nanoparticle array, comprising:
a lower substrate;
pins formed on both sides of a surface of the lower substrate; and
an upper substrate placed on a surface of the pins opposite the lower substrate;
wherein a channel structure formed by the upper substrate, the lower substrate, and the pins is nanosized such that a nanoparticle dispersion rises therein by capillary force.

20. The trench as set forth in claim 19, wherein the channel structure of the trench has a width of 2 to 4 cm, a height of 20 to 200 nm, and a length of 1 to 10 cm.
